(19) United States
(12) Patent Application Publication
(10) Pub. No.: US 2026/0032985 A1
(43) Pub. Date: Jan. 29, 2026

(54) SELECTIVE DEPOSITION OF HIGH-K DIELECTRIC MATERIAL IN GATE INTERFACE

(71) Applicant: Applied Materials, Inc., Santa Clara, CA (US)

(72) Inventors: Daniel Wei Ming BEH, Sunnyvale, CA (US); Zachary J. DEVEREAUX, Webberville, MI (US); Thomas KNISLEY, Livonia, MI (US); Bhaskar Jyoti BHUYAN, San Jose, CA (US); Mark J. SALY, Santa Clara, CA (US); Steven C. H. HUNG, Sunnyvale, CA (US)

(21) Appl. No.: 19/252,387

(22) Filed: Jun. 27, 2025

Related U.S. Application Data
(60) Provisional application No. 63/834,386, filed on Jul. 29, 2024.
(60) Provisional application No. 63/798,921, filed on May 2, 2025.

(51) Int. Cl. H10D 64/68; H01L 21/02; H10D 30/00; H10D 30/01; H10D 30/43; H10D 62/10; H10D 62/83; H10D 64/66

(52) U.S. Cl. CPC H10D 64/691; H01L 21/02205; H10D 30/014; H10D 30/019; H10D 62/121; H10D 62/83; H10D 64/667; H10D 64/685; H10D 64/693; H10D 30/43; H10D 30/502

(57) ABSTRACT

A processing method includes forming an interfacial layer on a surface of a channel comprising silicon (Si) located between a source and a drain on a semiconductor substrate including a low-κ dielectric layer, and selectively depositing a high-κ dielectric layer directly on the interfacial layer relative to the low-κ dielectric layer by exposing the semiconductor substrate to a metal-containing precursor, a purge gas, an alcohol, and the purge gas.

### CROSS REFERENCE TO RELATED APPLICATIONS

This application claims priority to U.S. Provisional Applications Ser. No. 63/834,386, filed Jul. 29, 2024, and Ser. No. 63/798,921, filed May 2, 2025, each of which is herein incorporated by reference in its entirety.

### BACKGROUND

### Field

Embodiments described herein generally relate to semiconductor device fabrication, and more particularly, to systems and methods of forming a high quality high-κ dielectric material layer in a semiconductor structure.

### Description of the Related Art

As metal-oxide-semiconductor field-effect transistors (MOSFETs) have decreased in size to achieve high device performance and low power consumption, the thickness of a traditional silicon dioxide (SiO₂) gate dielectric has to be decreased in order to enhance the transistor speed, which unfortunately also causes an increase in leakage current. As a result, replacing the silicon dioxide gate dielectric with a high-κ dielectric material has been inevitable to achieve further scaling without hindering leakage performance. Gate-all-around FETs (GAA FETs) provide design flexibility, low operational voltage, high drive currents, high computational speed, and excellent performance within a smaller footprint area. In a GAA nanosheet structure, a low-κ inner spacer with a small dielectric constant is introduced to improve parasitic capacitance between source/drain (S/D) epitaxial layers and metal gates. However, high-κ gate dielectric material undesirably deposited on a gate spacer or an inner spacer reduces an effective gate length in this structure, increasing parasitic capacitance between the S/D epitaxial layers and metal gates.

Therefore, there is a need for methods enabling selective deposition of high-κ gate dielectric material on metal gates.

### SUMMARY

Embodiments of the present disclosure provide a processing method. The processing method includes forming an interfacial layer on a surface of a channel comprising silicon (Si) located between a source and a drain on a semiconductor substrate including a low-κ dielectric layer, and selectively depositing a high-κ dielectric layer directly on the interfacial layer relative to the low-κ dielectric layer by exposing the semiconductor substrate to a metal-containing precursor, a purge gas, an alcohol, and the purge gas.

Embodiments of the present disclosure also provide a processing method. The processing method includes forming an interfacial layer comprising silicon oxide (SiOx) on a surface of a channel comprising silicon (Si) located between a source and a drain on a semiconductor substrate including a low-κ dielectric layer, and selectively depositing a high-κ dielectric layer comprising hafnium oxide (HfO₂) directly on the interfacial layer relative to the low-κ dielectric layer by exposing the semiconductor substrate to a hafnium-containing precursor, a purge gas, an alcohol, and the purge gas.

Embodiments of the present disclosure further provide a method of manufacturing an electronic device. The method includes forming an interfacial layer comprising silicon oxide (SiO₂) on a surface of a channel comprising silicon (Si) located between a source and a drain on a semiconductor substrate including a low-κ dielectric layer. selectively depositing a high-κ dielectric layer directly on the interfacial layer relative to the low-κ dielectric layer. depositing a dipole layer directly on the high-dielectric layer. annealing the semiconductor substrate at a temperature of less than or equal to 1000° C. to drive in metallic atoms from the dipole layer and densify the high-κ dielectric layer, removing the dipole layer to expose the surface of the high-κ dielectric layer, and depositing a capping layer directly on a surface of the high-κ dielectric layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a cluster tool, according to one or more embodiments of the present disclosure.

FIG. 2 depicts a process flow diagram of a method of forming a gate interface including a high-κ gate dielectric layer in a semiconductor structure that may form a horizontally stacked gate-all-around field-effect transistor (GAA FET) nanosheet structure, according to one embodiment.

FIGS. 3A, 3B, 3C, 3D, 3E, 3F, 3G, 3H, and 31 are cross-sectional views of a portion of a semiconductor structure corresponding to various states of the method of FIG. 2.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

As gate structures scale to smaller dimensions, new material structures are being sought to provide improvements. The use of high-κ dielectric materials increases the dielectric constant of the gate structure over conventional gate structures that utilize materials such as silicon oxide. However, similar to silicon oxide, as the thickness of a gate structure is reduced, leakage currents increase. For example, gate leakage increases as the effective oxide thickness decreases. Hence, the inverse relationship between gate leakage and effective oxide thickness may form a limit on the performance of the transistor and the device produced.

The embodiments described herein provide systems and methods for increasing an effective gate length in a horizontally stacked gate-all-around field-effect transistor (GAA FET) nanosheet structure, by avoiding deposition of high-κ gate dielectric material on a gate spacer or an inner spacer, improving parasitic capacitance between the S/D epitaxial layers and metal gates.

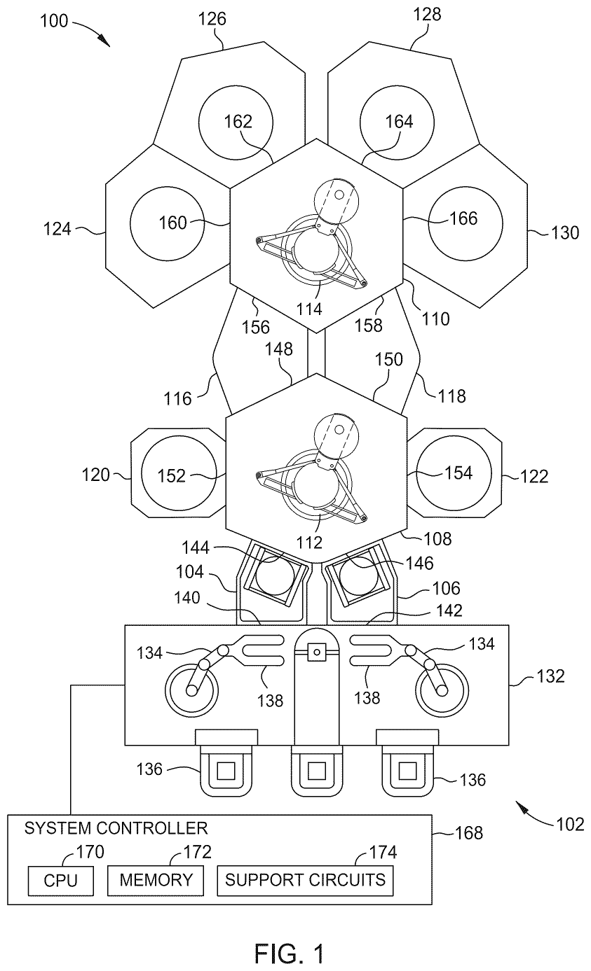

FIG. 1 is a schematic top view of a multi-chamber cluster tool 100, according to one or more embodiments of the present disclosure. The cluster tool 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the cluster tool 100 can be processed in and transferred between the various chambers without exposing the substrates to an ambient environment exterior to the cluster tool 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the cluster tool 100. Accordingly, the cluster tool 100 may provide for an integrated solution for some processing of substrates.

Examples of a cluster tool that may be suitably modified in accordance with the teachings provided herein include the Endura®, Producer® or Centura® integrated cluster tools or other suitable cluster tools commercially available from Applied Materials, Inc., located in Santa Clara, California. It is contemplated that other cluster tools (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a wafer. In some examples, the processing chamber 120 can be a Selectra™ Etch chamber available from Applied Materials of Santa Clara, Calif., capable of etching, or a Clarion™ or SiCoNi™ Preclean chamber available from Applied Materials of Santa Clara, Calif., capable of performing a cleaning process, the processing chamber 122 can be a rapid thermal processing (RTP) chamber, such as RADOX™ chamber, available from Applied Materials of Santa Clara, Calif., capable of performing thermal oxidation, rapid thermal processing (RTP) anneal, or ashing, the processing chambers 124, 126, and 128 can be a Centura® Epi chamber, Volta® CVD/ALD chamber, or EnCoRe® PVD chamber available from Applied Materials of Santa Clara, Calif., capable of performing respective deposition processes, and the processing chamber 130 can be a Centura® decoupled plasma nitridation (DPN) chamber available from Applied Materials of Santa Clara, Calif.

A system controller 168 is coupled to the cluster tool 100 for controlling the cluster tool 100 or components thereof. For example, the system controller 168 may control the operation of the cluster tool 100 using a direct control of the chambers 104, 106, 108, 110, 116, 118, 120, 122, 124, 126, 128, 130 of the cluster tool 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the cluster tool 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other cluster tools can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a cluster tool.

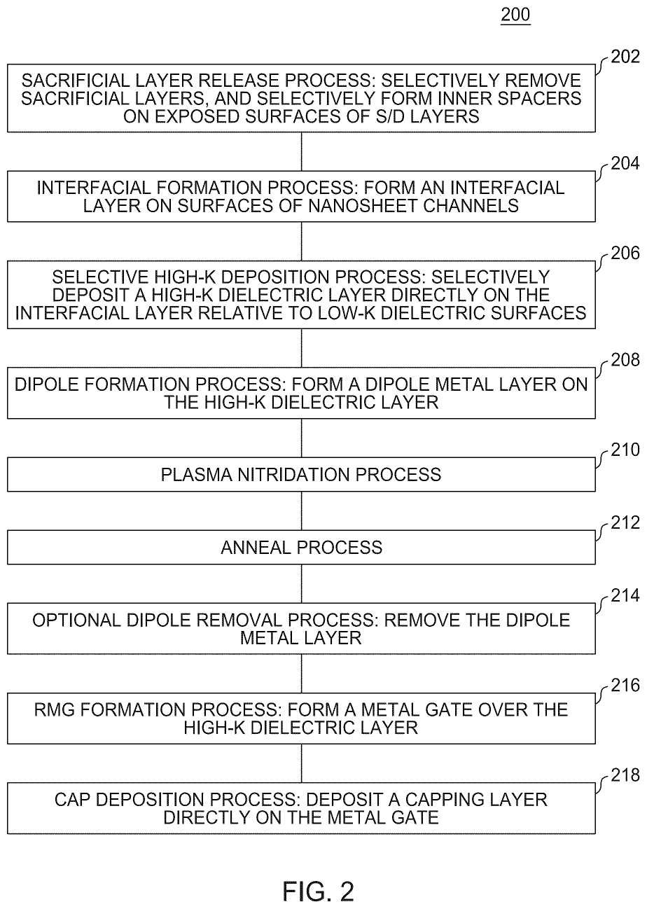

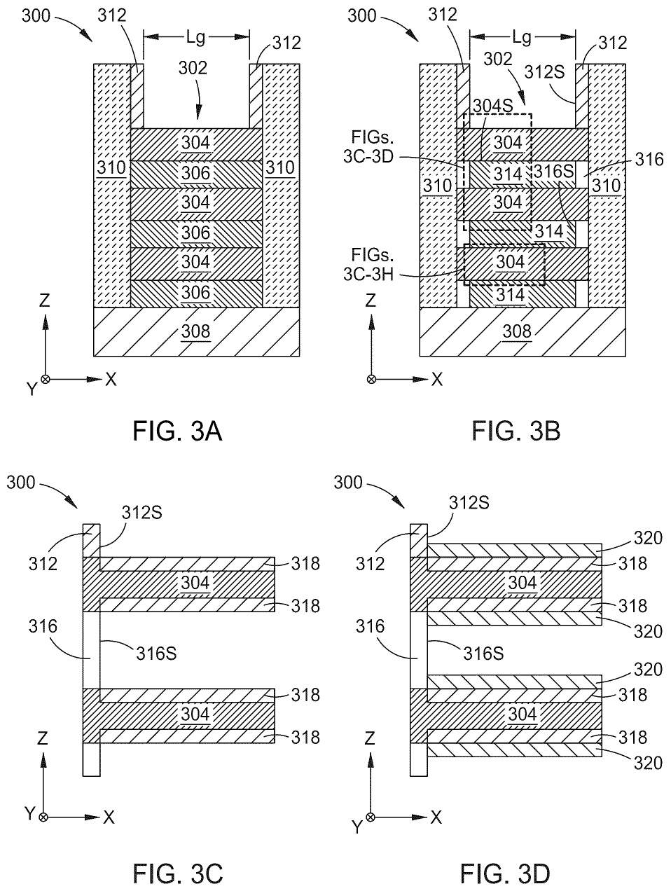

FIG. 2 depicts a process flow diagram of a method 200 of forming a gate interface including a high-κ gate dielectric layer in a semiconductor structure 300 forming a portion of a horizontally stacked gate-all-around field-effect transistor (GAA FET) nanosheet structure, according to one or more embodiments of the present disclosure. FIGS. 3A, 3B, 3C, 3D, 3E, 3F, 3G, 3H, and 3I are cross-sectional views of a portion of the semiconductor structure 300 corresponding to various states of the method 200. It should be understood that FIGS. 3A, 3B, 3C, 3D, 3E, 3F, 3G, 3H, and 3I illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

The semiconductor structure 300 shown in FIG. 3A includes a fin-shaped column 302 including a stack of alternating nanosheet channels 304 and sacrificial layers 306 epitaxially grown on a semiconductor substrate 308. The semiconductor structure 300 further includes source/drain (S/D) epitaxial (epi) layers 310 on both sides of the fin-shaped column 302 in the X direction. A gate spacer 312 is formed over the S/D epi layer in the X direction and above the fin-shaped column 302 in the Z direction. A gate length L_{g} is a distance between adjacent gate spacers 312 in the X direction, shown in FIG. 3A.

The fin-shaped column 302 may have a width in the X direction of between about 6 nm and about 200 nm. As shown, the stack includes three nanosheet channels 304 and three sacrificial layers 306. However, in some embodiments, the fin-shaped column 302 includes between 3 and 8 pairs of the nanosheet channels 304 and the sacrificial layers 306.

The nanosheet channels 304 may be formed of silicon (Si) or indium gallium zinc oxide (IGZO), each having a thickness of between about 3 nm and about 10 nm in the Z direction. The sacrificial layers 306 may be formed of silicon germanium (SiGe) with a ratio of germanium (Ge) ranging between about 5% and about 60%, for example, about 25%. The sacrificial layers 306 may each have a thickness of between about 4 nm and about 20 nm, for example, about 8 nm, in the Z direction.

The term “substrate” as used herein refers to a layer of material that serves as a basis for subsequent processing operations and includes a surface to be cleaned. The semiconductor substrate 308 may be a silicon based material or any suitable insulating materials or conductive materials as needed. The substrate may include a material such as crystalline silicon (e.g., Si<100>or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

In a p-type MOS (p-MOS) device region of the semiconductor structure 300, the S/D epi layer 310 may be formed of epitaxially grown silicon germanium (SiGe) with a ratio of germanium (Ge) ranging between about 10% and about 50%, doped with p-type dopants such as boron (B) or gallium (Ga), with a concentration of between about 10¹⁹ cm⁻³ and 5 x·10²¹ cm⁻³, depending upon the desired conductive characteristic of the S/D epi layer 310.

In an n-type MOS (N-MOS) device region of the semiconductor structure 300, the S/D epi layer 310 may be formed of epitaxially grown silicon (Si) doped with n-type dopants such as phosphorus (P), arsenic (As), or antimony (Sb), with a concentration of between about 10¹⁹ cm⁻³ and 5 x·10²¹ cm⁻³, depending upon the desired conductive characteristic of the S/D epi layer 310.

The gate spacers 312 may be formed of low-κ dielectric material, such as silicon nitride (SiN), silicon carbonitride (SiCN), silicon oxynitride (SiON), silicon oxycarbide (SiOC), silicon oxy nitride (SiOCN), silicon oxy boronitride (SiBCN), silicon oxide (SiO₂), or any combination thereof.

The method 200 begins with block 202, in which a sacrificial layer release process is performed to selectively remove the sacrificial layers 306 to form cavities 314 between adjacent nanosheet channels 304, and form inner spacers 316 selectively on exposed surfaces of the S/D epi layers 310 within the cavities 314 (e.g., sidewalls of the cavities 314), as shown in FIG. 3B.

The sacrificial layer release process includes a selective etch process, and a selective deposition process. The selective etch process may include any suitable dry etch process using hydrogen (H₂), ammonia (NF₃), and/or ammonia (NF₃) plasma species, or any suitable wet etch process using hydrofluoric (HF) acid, performed in a processing chamber, such as the processing chamber 120 shown in FIG. 1. The selective deposition process may include any appropriate deposition process, such as a plasma-enhanced chemical vapor deposition (PECVD) process, performed in a processing chamber, such as the processing chamber 124, 126, or 128 shown in FIG. 1.

The inner spacers 316 may be formed of low-κ dielectric material, such as silicon nitride (Si₃N₄), silicon carbon nitride (SiCN), silicon oxynitride (SiON), oxycarbide (SiOC), or silicon oxy-carbon-nitride (SiOCN).

In block 204, an interfacial formation process is performed to form an interfacial layer 318 on the surfaces 304S of the nanosheet channels 304, as shown in FIG. 3C. The interfacial layer 318 is formed of silicon oxide (SiO₂).

The interfacial formation process may include any appropriate deposition process, such as an atomic layer deposition (ALD), chemical vapor deposition (CVD), physical vapor deposition process (PVD), molecular beam epitaxy (MBE), metal-organic chemical vapor deposition (MOCVD), or spin-on, performed in a processing chamber, such as the processing chamber 124 shown in FIG. 1.

In some embodiments, the interfacial formation process includes etching the surfaces 304S (FIG. 3B) of the nanosheet channels 304 and forming an oxide on the surfaces 304S of the nanosheet channels 304 performed in a processing chamber, such as the processing chamber 120 shown in FIG. 1.

The interfacial formation process may include a wet etch process, such as an O3/SC1 clean process using an ozone (O₃) (e.g., 5 ppm) with a Standard Clean 1 (SC1) etch solution including NH₄OH (ammonium hydroxide), H₂O₂ (hydrogen peroxide), and H₂O (water).

The interfacial formation process may include a wet etch process, such as a clean process using a dilute hydrofluoric acid (dHF). The dHF may have a dilution ratio of greater than about 100:1, such as 130:1, to etch away native oxide the surfaces 304S of the nanosheet channels 304 to form a hydrophobic surface (i.e., the interfacial layer 318).

The interfacial layer 318 may have a thickness of between about 1 Å and about 10 Å, or between about 6 Å and about 8 Å.

In block 206, a selective high-κ deposition process is performed to selectively deposit a high-κ dielectric layer 320 directly on the interfacial layer 318 (e.g., silicon oxide (SiO₂)) relative to low-κ dielectric surfaces (e.g., surfaces 312S) (FIG. 3B) of the gate spacers 312 and surfaces 316S of the inner spacers 316), as shown in FIG. 3D. The high-κ dielectric layer 320 may be formed of high-κ dielectric material, such as hafnium dioxide (HfO₂), zirconium dioxide (ZrO₂), hafnium zirconium oxide (Hf_{0.5}Zr_{0.5}O₂), titanium oxide (TiO₂), tantalum oxide (Ta₂O₅), ytterbium oxide (Y₂O₃), aluminum oxide (Al₂O₃), lanthanide-containing oxide, or any alloys thereof. The high-κ dielectric layer 320 has a thickness of between about 1 Å and about 50 Å, for example, between about 25 Å and about 40 Å. The selective high-κ deposition process may be performed in a processing chamber, such as the processing chamber 126 or 128 shown in FIG. 1.

In some embodiments, the selective high-κ deposition process may include any appropriate deposition process, such as a chemical vapor deposition (CVD) process or a physical vapor deposition process (PVD) process, in which a metal-containing precursor, a purge gas, an alcohol, and the purge gas are delivered to the exposed surface of the semiconductor structure 300. In some embodiments, the metal-containing precursor The metal may be a transition metal, such as hafnium (Hf), zirconium (Zr), titanium (Ti), or tantalum (Ta), a rare-earth metal, such as lanthanum (La), ytterbium (Yb), yttrium (Y), or cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), lutetium (Lu), an alkaline earth metal, such as strontium (Sr), or other metal such as aluminum (Al).

In one example, the metal-containing precursor includes one or more of a hafnium cyclopentadiene compound, a hafnium amino compound, a hafnium alkyl compound, a hafnium alkoxy compound, isomers thereof, complexes thereof, abducts thereof, or salts thereof. In one or more embodiments, the hafnium-containing precursor includes one or more of hafnium tetrachloride (HfCl₄), Tetrakis(ethylmethylamido)hafnium (TEMAHf), tris(dimethylamido)cyclopentadienyl hafnium, bis(methylcyclopentadiene)dimethylhafnium ((MeCp)₂HfMe₂), bis(methylcyclopentadiene)methylmethoxyhafnium ((MeCp)₂Hf(OMe)(Me)), bis(cyclopentadiene) dimethylhafnium ((Cp)₂HfMe₂), tetra(tert-butoxy) hafnium, hafnium isopropoxide ((iPrO)₄Hf), tetrakis(dimethylamino) hafnium (TDMAH), tetrakis(diethylamino) hafnium (TDEAH), isomers thereof, complexes thereof, abducts thereof, or salts thereof.

In one example, the metal-containing precursor includes one or more of hafnium tetrachloride (HfCl₄) and Tetrakis(ethylmethylamido) hafnium (TEMAHf), tris(dimethylamido)cyclopentadienyl hafnium.

The alcohol used in the selective high-κ deposition process has a general formula of R¹—O—R², where R¹ and R² are independently selected from H, an alkyl group, or an aryl group having between 1 and 12 carbon atoms. In one or more embodiments, the alcohol includes tert-butanol ((CH₃)₃COH).

In some embodiments where the high-κ dielectric layer 320 includes hafnium zirconium oxide (e.g., Hf_{0.5}Zr_{0.5}O₂), the high-κ dielectric layer 320 can be selectively deposited directly on the interfacial layer 318, by exposing the semiconductor structure 300 to a first metallic precursor (e.g., a hafnium-containing precursor), a purge gas, an alcohol, a purge gas, a second metallic precursor, (e.g., a zirconium-containing precursor), and a purge gas in any suitable order.

Advantageously, it has been found that the hafnium-containing precursor comprising one or more of hafnium tetrachloride (HfCl₄), Tetrakis(ethylmethylamido)hafnium (TEMAHf), tris(dimethylamido)cyclopentadienyl hafnium to deposit the high-κ dielectric layer 320 exhibits inherent selectivity in forming on the interfacial layer 318 relative to the low-κ dielectric surfaces (e.g., surfaces 312S of the gate spacers 312 and surfaces 316S of the inner spacers 316).

It has been advantageously and unexpectedly found that using tris(dimethylamido)cyclopentadienyl hafnium and tert-butanol to deposit the high-κ dielectric layer 320 exhibits inherent selectivity in forming on the interfacial layer 318 relative to the low-κ dielectric surfaces (e.g., surfaces 312S of the gate spacers 312 and surfaces 316S of the inner spacers 316).

The selective high-κ deposition process in block 206 may be repeated, to achieve a desired thickness of the high-κ dielectric layer 320.

In block 208, a dipole formation process is performed to form a dipole metal layer 322 on the high-κ dielectric layer 320, as shown in FIG. 3F.

The dipole formation process includes a blanket deposition of the dipole metal layer 322 over the entire exposed surface of the high-κ dielectric layer 320 in the semiconductor structure 300, and a subsequent lithography and etch process to pattern the dipole metal layer 322 (i.e., to form the dipole metal layer 322 in some regions of the semiconductor structure 300, and not in some other regions of the semiconductor structure 300). The deposition process may be performed in a processing chamber, such as the processing chamber 126 or 128 shown in FIG. 1.

In some embodiments, the dipole metal layer 322 is formed of material containing n-type dopants in high-κ dielectric material. Suitable n-type dopants include rare-earth metal, such as lanthanum (La), yttrium (Y), and ytterbium (Yb), or any metallic substance having Fermi level higher than that of hafnium (Hf) such as magnesium (Mg). Suitable lanthanum (La)-containing materials include lanthanum oxide (La₂O₃), lanthanum nitride (LaN), lanthanum (La), and titanium lanthanum nitride (TiLaN). In a subsequent anneal process, n-type dopant species from the dipole metal layer 322 are diffused and incorporated into the underlying high-κ dielectric layer 320, which lowers the threshold voltage Vₜ in an n-MOSFET. An amount of n-type dopant species determines a change in the threshold voltage Vt. For example, incorporation of lanthanum (La) species of between about 1 atomic % and about 5 atomic % in the high-κ dielectric layer 320 changes the threshold voltage Vₜ by about 10 eV.

In some other embodiments, the dipole metal layer 322 is formed of material containing p-type dopants in high-κ dielectric material. Suitable p-type dopants include aluminum (Al), niobium (Nb), tantalum (Ta), or any metallic substance having Fermi level lower than that of hafnium (Hf). Suitable aluminum (Al)-containing materials include aluminum oxide (Al₂O₃). Suitable niobium (Nb)-containing materials include niobium nitride (NbN), niobium oxide (NbOx), and titanium niobium nitride (TiNbN). In a subsequent anneal process, p-dopant species are diffused and incorporated into the underlying first high-κ gate dielectric layer 320, which lowers the threshold voltage Vₜ in a p-MOSFET. An amount of p-type dopants determines a change in the threshold voltage Vₜ. For example, incorporation of aluminum (Al) species of between about 1 atomic % and about 5 atomic % in the high-κ dielectric layer 320 changes the threshold voltage Vₜ by about 80 eV. Incorporation of niobium (Nb) species of between about 1 atomic % and about 5 atomic % in the high-κ dielectric layer 320 changes the threshold voltage Vₜ by about 120 eV.

The blanket deposition process may include an atomic layer deposition (ALD) process, in which a metal precursor pulse is delivered to the exposed surface of the semiconductor structure 300. The ALD process may be performed at a temperature of between 100° C. and about 500° C., for example, about 300° C., about 450° C., or 500° C., at a pressure of between about 0 mTorr and about 50 Torr. The dipole metal layer 322, as deposited by the ALD process, may have a thickness of between about 3 Å and about 20 Å, for example, about 5 Å. Without intending to be bound by theory, it is believed that, when the dipole metal layer 322 is deposited on the high-κ dielectric layer 320 by ALD at a temperature of 450° C. or 500° C., for example, metallic atoms from the dipole metal layer 322 are driven into the high-κ dielectric layer 212.

In block 210, a plasma nitridation process is performed to insert nitrogen atoms into vacancies and defects in the high-κ dielectric layer 320. The plasma nitridation process may be a decoupled plasma nitridation (DPN) process performed in a processing chamber, such as the processing chamber 130 shown in FIG. 1.

The plasma nitridation process exposes the high-κ dielectric layer 320 to nitrogen-containing reactant, which may allow nitrogen radicals or nitrogen atoms to be incorporated within the high-κ dielectric layer 320, throughout the thickness of the high-κ dielectric layer 320. Gases that may be used in the plasma process include nitrogen containing gas, such as nitrogen (N₂), ammonia (NH₃), hydrazine (N₂H₄), or mixtures thereof, or a co-flow of nitrogen radicals (N₂*) and hydrogen radicals (H*). In one example, the nitrogen gas is ammonia (NH₃) mixed with about 3% to about 8% of nitrogen (N₂). The plasma nitridation process may not change a thickness of the high-κ dielectric layer 320 as a result of the nitrogen incorporation into vacancies and defects in the high-κ dielectric layer 320. The plasma nitridation process may increase the overall κ-value of the high-κ dielectric layer 320, for example, by about 25%.

In some embodiments, the nitrogen-containing reactant includes a substituted or unsubstituted alkyl hydrazine. In some embodiments, the alkyl hydrazine comprises between 1 carbon and 6 carbons. In one or more embodiments, the alkyl hydrazine is t-butyl hydrazine.

The nitridation process may be performed for between about 10 seconds and about 300 seconds, at a temperature of between about 500° C. and about 1000° C., for example, between about 600° C. and about 1000° C., between about 700° C. and about 1000° C., between about 750° C. and about 950° C.

In block 212, an anneal process is performed to passivate the remaining chemical bonds in the plasma nitridated high-κ dielectric layer 320 and densify the high-κ dielectric layer 320. The anneal process may include a spike thermal anneal process in a nitrogen (N₂) and argon (Ar) ambient, performed in a processing chamber, such as the processing chamber 122 shown in FIG. 1.

The anneal process may passivate metastable nitrogen bonds formed in the plasma nitridation process in block 210 and crystallization of the amorphous the high-κ dielectric layer 320 may occur. The anneal process may further drive metallic atoms from the dipole metal layer 322 into the high-κ dielectric layer 212.

The spike thermal anneal process may be performed for between about 1 second and about 30 seconds, at a temperature of less than or equal to 1000° C., for example, between about 700° C. and about 850° C., and at a pressure of between about 10 Torr and 740 Torr.

In block 214, an optional dipole removal process is performed to remove the dipole metal layer 322, as shown in FIG. 3G. The optional dipole removal process may include any appropriate etching process, such as a wet etch process using one or more of ammonium hydroxide (NH₄OH) or water (H₂O). In some embodiments, the pre-clean process includes using a ratio of DI:NH₄OH of between about 100:1 DI:NH₄OH and about 5:1 DI:NH₄OH.

In block 216, a replacement metal gate (RMG) formation process is performed to form a metal gate 326 (e.g., titanium nitride (TiN), titanium aluminum carbide (TiAlC), tantalum aluminum (TaAl), or tungsten (W)) over the high-κ dielectric layer 320, as shown in FIG. 3H.

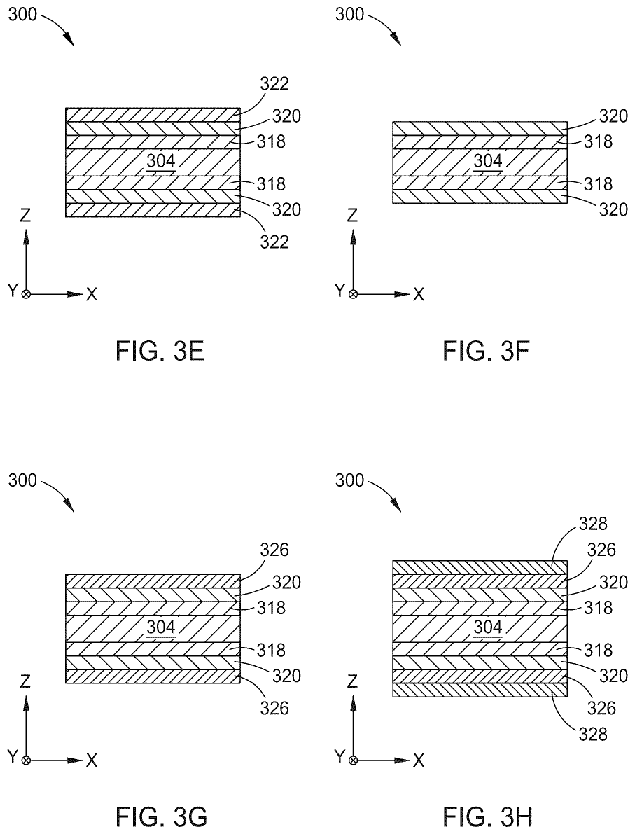

In block 218, a cap deposition process is performed to deposit a capping layer 328 directly on the metal gate 326, as shown in FIG. 31. The cap deposition process may include any appropriate deposition process such as an atomic layer deposition (ALD), chemical vapor deposition (CVD), physical vapor deposition process (PVD), molecular beam epitaxy (MBE), metal-organic chemical vapor deposition (MOCVD), or spin-on, performed in a processing chamber, such as the processing chamber 124 shown in FIG. 1.

In one or more embodiments, the capping layer 328 is an in situ capping layer. The capping layer 328 may be formed of amorphous silicon, a metal, a metal carbide, a metal nitride, or a metal oxide. The capping layer 328 may have a thickness of between about 5 Å and 20 Å.

The embodiments described herein provide methods and systems for selectively depositing high-κ gate dielectric material on nanosheet channels in a horizontally stacked gate-all-around field-effect transistor (GAA FET) nanosheet structure, without depositing high-κ gate dielectric material on gate spacers or inner spacers. This selective deposition increases an effective gate length improving parasitic capacitance between the S/D epitaxial layers and metal gates.

The methods include forming a silicon oxide (SiO₂) interfacial layer on silicon (Si) surface, and depositing high-κ dielectric material selectively on the interfacial layer but not on low-κ dielectric surfaces.

While the foregoing is directed to embodiments of the present disclosure, other and further embodiments of the disclosure may be devised without departing from the basic scope thereof, and the scope thereof is determined by the claims that follow.

1. A processing method comprising:
forming an interfacial layer on a surface of a channel comprising silicon (Si) located between a source and a drain on a semiconductor substrate including a low-κ dielectric layer; and
selectively depositing a high-κ dielectric layer directly on the interfacial layer relative to the low-κ dielectric layer by exposing the semiconductor substrate to a metal-containing precursor, a purge gas, an alcohol, and the purge gas.

2. The processing method of claim 1, wherein the low-κ dielectric layer comprises one or more of silicon nitride (SiN), silicon carbonitride (SiCN), silicon oxynitride (SiON), silicon oxycarbide (SiOC), or silicon carboxynitride (SiCON).

3. The processing method of claim 1, wherein the interfacial layer comprises silicon oxide (SiO₂).

4. The processing method of claim 1, wherein the high-κ dielectric layer comprises one or more of hafnium oxide (HfO₂), zirconium oxide (ZrO₂), hafnium zirconium oxide (Hf_{0.5}Zr_{0.5}O₂), titanium oxide (TiO₂), tantalum oxide (Ta₂O₅), a lanthanide-containing oxide, or alloys thereof.

5. The processing method of claim 1, wherein the metal-containing precursor includes a hafnium-containing precursor comprising one or more of a hafnium cyclopentadiene compound, a hafnium amino compound, a hafnium alkyl compound, a hafnium alkoxy compound, isomers thereof, complexes thereof, abducts thereof, or salts thereof.

6. The processing method of claim 5, wherein the hafnium-containing precursor comprises one or more of hafnium tetrachloride (HfCl₄), Tetrakis(ethylmethylamido)hafnium (TEMAHf), tris(dimethylamido)cyclopentadienyl hafnium, bis(methylcyclopentadiene) dimethylhafnium ((MeCp)₂HfMe₂), bis(methylcyclopentadiene) methylmethoxyhafnium ((MeCp)₂Hf(OMe)(Me)), bis(cyclopentadiene) dimethylhafnium ((Cp)₂HfMe₂), tetra(tert-butoxy) hafnium, hafnium isopropoxide ((iPrO)₄Hf), tetrakis(dimethylamino) hafnium (TDMAH), tetrakis(diethylamino) hafnium (TDEAH), isomers thereof, complexes thereof, abducts thereof, or salts thereof.

7. The processing method of claim 4, wherein the high-κ dielectric layer comprises hafnium oxide (HfOx).

8. The processing method of claim 1, wherein the alcohol has a general formula of R¹—O—R², where R¹ and R² are independently selected from H, an alkyl group, or an aryl group having between 1 and 12 carbon atoms.

9. The processing method of claim 8, wherein the alcohol comprises tert-butanol.

10. The processing method of claim 1, wherein the high-κ dielectric layer is selectively deposited at a temperature of between 20° C. and 600° C.

11. The processing method of claim 1, further comprising forming a blocking layer on the low-κ dielectric layer to inhibit deposition of the high-κ dielectric layer on the low-κ dielectric layer.

12. The processing method of claim 1, comprising repeating one or more operations of the processing method to deposit the high-κ dielectric layer to a predetermined thickness.

13. A processing method comprising:
forming an interfacial layer comprising silicon oxide (SiOx) on a surface of a channel comprising silicon (Si) located between a source and a drain on a semiconductor substrate including a low-κ dielectric layer; and
selectively depositing a high-κ dielectric layer comprising hafnium oxide (HfO₂) directly on the interfacial layer relative to the low-κ dielectric layer by exposing the semiconductor substrate to a hafnium-containing precursor, a purge gas, an alcohol, and the purge gas.

14. The processing method of claim 13, wherein the hafnium-containing precursor comprises one or more of hafnium tetrachloride (HfCl₄), Tetrakis(ethylmethylamido)hafnium (TEMAHf), tris(dimethylamido)cyclopentadienyl hafnium, bis(methylcyclopentadiene) dimethylhafnium ((MeCp)₂HfMe₂), bis(methylcyclopentadiene) methylmethoxyhafnium ((MeCp)₂Hf(OMe)(Me)), bis(cyclopentadiene) dimethylhafnium ((Cp)₂HfMe₂), tetra(tert-butoxy) hafnium, hafnium isopropoxide ((iPrO)₄Hf), tetrakis(dimethylamino) hafnium (TDMAH), tetrakis(diethylamino) hafnium (TDEAH), isomers thereof, complexes thereof, abducts thereof, or salts thereof.

15. The processing method of claim 13, wherein the alcohol comprises tert-butanol.

16. A method of manufacturing an electronic device, the method comprising:
forming an interfacial layer comprising silicon oxide (SiO₂) on a surface of a channel comprising silicon (Si) located between a source and a drain on a semiconductor substrate including a low-κ dielectric layer;
selectively depositing a high-κ dielectric layer directly on the interfacial layer relative to the low-κ dielectric layer;
depositing a dipole layer directly on the high-κ dielectric layer;
annealing the semiconductor substrate at a temperature of less than or equal to 1000° C. to drive in metallic atoms from the dipole layer and densify the high-κ dielectric layer;
removing the dipole layer to expose the surface of the high-κ dielectric layer; and
depositing a capping layer directly on a surface of the high-κ dielectric layer.

17. The method of claim 16, further comprising:
depositing a metal gate directly on the surface of high-κ dielectric layer, the metal gate comprising one or more of titanium aluminum (TiAl), titanium aluminum carbide (TiAlC), or tantalum aluminum (TaAl); and
depositing a capping layer directly on a surface of the metal gate.

18. The method of claim 16, wherein selectively depositing the high-κ dielectric layer comprises exposing the semiconductor substrate alternately to a metal-containing precursor, a purge gas, an alcohol, and a purge gas.

19. The method of claim 18, wherein the metal-containing precursor includes a hafnium-containing precursor comprising one or more of hafnium tetrachloride (HfCl₄), Tetrakis(ethylmethylamido)hafnium (TEMAHf), or tris(dimethylamido)cyclopentadienyl hafnium, and the alcohol has a general formula of R¹—O—R², where R¹ and R² are independently selected from H, an alkyl group, or an aryl group having between 1 and 12 carbon atoms.

20. The method of claim 16, wherein the capping layer comprises one or more of amorphous silicon, a metal, a metal carbide, a metal nitride, or a metal oxide.
